(19) United States
(12) Patent Application Publication
(10) Pub. No.: US 2026/0136897 A1
(43) Pub. Date: May 14, 2026

(54) SEMICONDUCTOR DEVICE

(71) Applicant: Sony Semiconductor Solutions Corporation, Kanagawa (JP)

(72) Inventor: Takahiro Mayumi, Kanagawa (JP)

(21) Appl. No.: 19/121,310

(22) PCT Filed: Oct. 13, 2023
(86) PCT No.: PCT/JP2023/037259

§ 371 Date: Apr. 15, 2025

(30) Foreign Application Priority Data
Nov. 25, 2022 (JP) 2022-187913

(51) Int. Cl. H10P 74/00; H10F 39/00; H10P 74/20

(52) U.S. Cl. CPC H10P 74/273; H10F 39/8037; H10F 39/811; H10P 74/203

(57) ABSTRACT

A semiconductor device includes a plurality of signal lines, a first inspection terminal, a detection circuit, a second inspection terminal, and a protection element. The plurality of signal lines extends in a first direction and arranged in a second direction that intersects the first direction. The first inspection terminal is electrically coupled to one end of the signal lines and supplies an inspection signal to the signal lines. The detection circuit is electrically coupled to another end of the signal lines and detects a defect in the signal lines. The second inspection terminal supplies a control signal that controls a detection operation of the detection circuit. The protection element is electrically coupled to the second inspection terminal and absorbs a surge.

### TECHNICAL FIELD

The present disclosure relates to a semiconductor device.

### BACKGROUND ART

PTL 1 discloses a semiconductor device that constructs an imaging element. In the semiconductor device, a plurality of semiconductor substrates is bonded and stacked. One semiconductor substrate includes a pixel array in which a plurality of pixels each including a light-receiving element is arranged in a matrix, and a plurality of wirings disposed for each respective pixel row and each respective pixel column. On another semiconductor substrate, a circuit is formed that executes, for example, processing of a pixel signal read out from each pixel.

In such a semiconductor device, presence or absence of a defect in any of the wirings affects a manufacturing yield. Therefore, in a manufacturing process of the semiconductor device, the presence or absence of a defect in any of the wirings is inspected before bonding of the semiconductor substrates.

### CITATION LIST

### Patent Literature

PTL 1: Japanese Unexamined Patent Application Publication No. 2021-103760

### SUMMARY OF THE INVENTION

In the semiconductor device disclosed in PTL 1 described above, a countermeasure against an electrostatic discharge (ESD) breakdown due to an occurrence of a surge has been required in an inspection step during a manufacturing process.

A semiconductor device according to a first embodiment of the present disclosure includes a plurality of signal lines, a first inspection terminal, a detection circuit, a second inspection terminal, and a protection element. The plurality of signal lines extends in a first direction and arranged in a second direction that intersects the first direction. The first inspection terminal is electrically coupled to one end of the signal lines and supplies an inspection signal to the signal lines. The detection circuit is electrically coupled to another end of the signal lines and detects a defect in the signal lines. The second inspection terminal supplies a control signal that controls a detection operation of the detection circuit. The protection element is electrically coupled to the second inspection terminal and absorbs a surge.

A semiconductor device according to a second embodiment of the present disclosure includes the semiconductor device according to the first embodiment in which the protection element is electrically coupled between the second inspection terminal and a power supply line. In addition, the signal lines, the first inspection terminal, the detection circuit, the second inspection terminal, and the protection element are disposed on a side of a first surface of a first substrate. In the first substrate, the first inspection terminal and the power supply line are electrically isolated from each other, and the inspection signal and a power are each supplied independently.

A semiconductor device according to a third embodiment of the present disclosure includes the semiconductor device according to the second embodiment in which a second substrate is bonded to the side of the first surface of the first substrate, and the second substrate includes a wiring that electrically couples the first inspection terminal and the power supply line to each other.

### BRIEF DESCRIPTION OF THE DRAWINGS

FIG. 1 is a block circuit diagram illustrating a system of a solid-state imaging device mounted on a semiconductor device according to a first embodiment of the present disclosure.

FIG. 2 is a circuit diagram illustrating a pixel and a pixel circuit of the solid-state imaging device illustrated in FIG. 1.

FIG. 3 is a block circuit diagram illustrating an inspection system for signal lines (vertical signal lines) of the solid-state imaging device illustrated in FIG. 1.

FIG. 4 is a sectional view of a main part of a substrate illustrating an inspection step for the signal lines in a manufacturing process of the solid-state imaging device illustrated in FIG. 1.

FIG. 5 is a schematic circuit diagram of the inspection system in the inspection step for the signal lines illustrated in FIG. 4.

FIG. 6 is a sectional view of a main part, corresponding to FIG. 4, of the solid-state imaging device illustrated in FIG. 1 as a final product after the manufacturing process is completed.

FIG. 7 is a schematic circuit diagram illustrating a coupling state of, for example, inspection terminals, a signal line, power supply lines, and a protection element in the solid-state imaging device illustrated in FIG. 6.

FIG. 8 is a schematic circuit diagram for describing a first inspection mode in the solid-state imaging device illustrated in FIG. 1.

FIG. 9 is a schematic circuit diagram for describing a second inspection mode in the solid-state imaging device illustrated in FIG. 1.

FIG. 10 is a schematic circuit diagram, corresponding to FIG. 5 or FIG. 7, illustrating an inspection system of a solid-state imaging device mounted on a semiconductor device according to a second embodiment of the present disclosure.

FIG. 11 is a schematic circuit diagram, corresponding to FIG. 5 or FIG. 7, illustrating an inspection system of a solid-state imaging device mounted on a semiconductor device according to a third embodiment of the present disclosure.

FIG. 12 is a schematic circuit diagram, corresponding to FIG. 5 or FIG. 7, illustrating an inspection system of a solid-state imaging device mounted on a semiconductor device according to a fourth embodiment of the present disclosure.

FIG. 13 is a schematic circuit diagram, corresponding to FIG. 5 or FIG. 7, illustrating an inspection system of a solid-state imaging device mounted on a semiconductor device according to a fifth embodiment of the present disclosure.

FIG. 14 is a block circuit diagram, corresponding to FIG. 3, illustrating an inspection system of a solid-state imaging device mounted on a semiconductor device according to a sixth embodiment of the present disclosure.

FIG. 15 is a block circuit diagram, corresponding to FIG. 3, illustrating an inspection system of a solid-state imaging device mounted on a semiconductor device according to a seventh embodiment of the present disclosure.

FIG. 16 is a block circuit diagram, corresponding to FIG. 3, illustrating an inspection system of a solid-state imaging device mounted on a semiconductor device according to an eighth embodiment of the present disclosure.

### MODES FOR CARRYING OUT THE INVENTION

Some embodiments of the present disclosure are described below in detail with reference to the drawings. It is to be noted that description is given in the following order.

### 1. First Embodiment

A first embodiment describes a first example in which the present technology is applied to a solid-state imaging device mounted on a semiconductor device. In the first embodiment, descriptions will be given of configurations including, for example, a system configuration of the solid-state imaging device, a circuit configuration of a pixel and a pixel circuit, a configuration of an inspection system, and sectional configurations of the solid-state imaging device in and after an inspection step in a manufacturing process of the solid-state imaging device. Furthermore, the first embodiment describes a configuration of a protection element incorporated in the inspection system.

### 2. Second Embodiment

A second embodiment describes the first example in which the configuration of the inspection system is changed in the solid-state imaging device mounted on the semiconductor device according to the first embodiment.

### 3. Third Embodiment

A third embodiment describes a second example in which the configuration of the inspection system is changed in the solid-state imaging device mounted on the semiconductor device according to the first embodiment.

### 4. Fourth Embodiment

A fourth embodiment describes a third example in which the configuration of the inspection system is changed in the solid-state imaging device mounted on the semiconductor device according to the first embodiment.

### 5. Fifth Embodiment

A fifth embodiment describes a fourth example in which the configuration of the protection element is changed in the solid-state imaging device mounted on the semiconductor device according to the first embodiment.

### 6. Sixth Embodiment

A sixth embodiment describes a fifth example in which the configuration of the inspection system is changed in the solid-state imaging device mounted on the semiconductor device according to the first embodiment.

### 7. Seventh Embodiment

A seventh embodiment describes a sixth example in which the configuration of the inspection system is changed in the solid-state imaging device mounted on the semiconductor device according to the first embodiment.

### 8. Eighth Embodiment

An eighth embodiment describes a seventh example in which the configuration of the inspection system is changed in the solid-state imaging device mounted on the semiconductor device according to the first embodiment.

### 9. Other Embodiments

### 1. First Embodiment

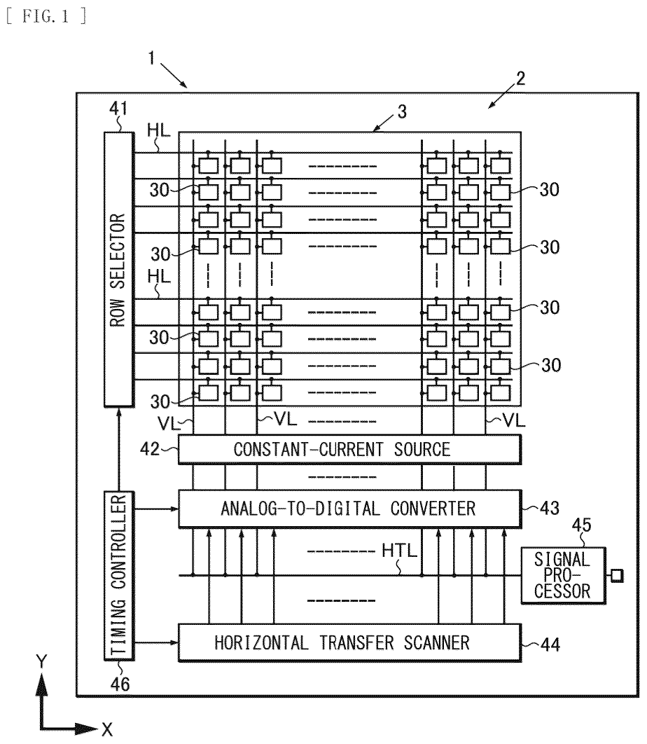

Description is given of a semiconductor device 1 according to the first embodiment of the present disclosure with reference to FIGS. 1 to 9.

Here, an arrow-X direction indicated as appropriate in the drawings indicates one planar direction of the semiconductor device 1 placed on a plane for convenience. An arrow-Y direction indicates another planar direction orthogonal to the arrow-X direction. In addition, an arrow-Z direction indicates an upward direction orthogonal to the arrow-X direction and the arrow-Y direction. That is, the arrow-X direction, the arrow-Y direction, and the arrow-Z direction exactly coincide with an X-axis direction, a Y-axis direction, and a Z-axis direction, respectively, of a three-dimensional coordinate system.

It is to be noted that these directions are each indicated to aid understanding of descriptions, and are not intended to limit directions used in the present technology.

### Configuration of Semiconductor Device 1

### (1) Overall Configuration of Semiconductor Device 1 and Solid-State Imaging Device 2

FIG. 1 illustrates an example of a system configuration of a solid-state imaging device 2 mounted on the semiconductor device 1 according to the first embodiment.

As illustrated in FIG. 1, the solid-state imaging device 2 of a back side illumination type is mounted on the semiconductor device I according to the first embodiment. More specifically, the solid-state imaging device 2 is constructed as a CMOS (Complementary Metal-Oxide-Semiconductor) image sensor. The solid-state imaging device 2 includes a pixel region 3 and a peripheral circuit.

### (2) Configuration of Pixel Region 3 of Solid-State Imaging Device 2

Signal lines VL, signal lines HL, and pixels 30 are disposed in the pixel region 3.

The signal lines VL are used as vertical signal lines. The signal lines VL, for example, extend in the arrow-Y direction as a column direction and are arranged at regular intervals in the arrow-X direction as a row direction.

In contrast, the signal lines HL are used as drive signal lines. The signal lines HL, for example, extend in the arrow-X direction and are arranged at regular intervals in the arrow-Y direction.

Here, a “first direction” according to the present technology corresponds to the arrow-Y direction, and a “second direction” according to the present technology corresponds to the arrow-X direction. Note that, in the present technology, the “first direction” and the “second direction” may be interchanged, and the “first direction” may be the arrow-X direction and the “second direction” may be the arrow-Y direction.

Each of the pixels 30 is disposed at an intersection of one of the signal lines VL and one of the signal lines HL. That is, the pixels 30 are arranged in each of the arrow-X direction and the arrow-Y direction.

Each of the pixels 30 includes a photoelectric conversion element. The photoelectric conversion element converts incident light into an electric charge and accumulates the electric charge.

Note that, the circuit configuration of each of the pixels 30 and a pixel circuit 5 will be described later.

### (3) Configuration of Peripheral Circuit of Solid-State Imaging Device 2

The peripheral circuit of the solid-state imaging device 2 includes, for example, a row selector 41, a constant-current source 42, an analog-to-digital converter 43, a horizontal transfer scanner 44, a signal processor 45, and a timing controller 46.

The row selector 41 includes a shift register, an address decoder, and the like. The row selector 41 scans, in the arrow-Y direction, the signal lines HL arranged in the pixel region 3 and selects the pixels 30 by row. Although a detailed description of the configuration is omitted, the row selector 41 includes, for example, two scanning systems, i.e., a readout scanning system and a sweep scanning system.

The readout scanning system sequentially selects and scans the pixels 30 on a row-by-row basis in the pixel region 3, and reads out the pixel signals accumulated in the pixels 30. The pixel signals read out from the pixels 30 include analog signals.

The sweep scanning system performs sweep scanning on the pixels 30 by row on which the readout scanning is to be performed by the readout scanning system, in advance of the readout scanning by a time of a shutter speed.

By the sweep scanning performed by the sweep scanning system, an unnecessary electric charge is swept out from the photoelectric conversion element of each of the pixels 30 to be read out, and the photoelectric conversion element is reset. By the resetting, what is called an electronic shutter operation is executed. Here, the electronic shutter operation includes an operation in which the electric charge of the photoelectric conversion element is discarded and exposure is newly started. In other words, the electronic shutter operation includes an operation of starting accumulation of the electric charge in the photoelectric conversion element.

The constant-current source 42 is coupled to each of the signal lines VL. The constant-current source 42 supplies a bias current to the pixels 30 on a row-by-row basis, as selected by the row selector 41, through the respective signal lines VL. The constant-current source 42 includes a plurality of current sources each including, for example, an insulated-gate field-effect transistor (IGFET).

Here, the IGFET is used in a sense including at least a metal-oxide-semiconductor field-effect transistor (MOSFET) and a metal-insulator-semiconductor field-effect transistor (MISFET).

The analog-to-digital converter 43 includes a plurality of analog-to-digital converters disposed for each respective pixel column in the pixel region 3. The analog-to-digital converter 43 is a column-parallel analog-to-digital converter that converts an analog pixel signal outputted through the signal line VL for each pixel column into an N-bit digital signal.

As the analog-to-digital converter 43, for example, a single-slope analog-to-digital converter, which is an example of a reference signal comparison type analog-to-digital converter, may be used. Alternatively, as the analog-to-digital converter 43, a successive approximation type analog-to-digital converter, a delta-sigma modulation type (ΔΣ modulation type) analog-to-digital converter, or the like may be used.

The horizontal transfer scanner 44 includes a shift register, an address decoder, and the like. The horizontal transfer scanner 44 controls scanning of the pixel columns and the address of the pixel columns when the signals of the pixels 30 in the pixel region 3 are to be read out. Under the control of the horizontal transfer scanner 44, the pixel signals converted into digital signals by the analog-to-digital converter 43 are read out into a horizontal transfer line HTL having a 2N-bit width on a per-pixel column basis.

The signal processor 45 performs predetermined signal processing on the digital pixel signals supplied through the horizontal transfer line HTL to generate two-dimensional image data. For example, the signal processor 45 performs, on the pixel signals, correction of a vertical line defect, a point defect, or the like, or signal processing such as clamping of the signals. In addition, the signal processor 45 may perform, on the pixel signals, signal processing including, for example, parallel-serial conversion, compression, encoding, addition, averaging, and intermittent operation.

The signal processor 45 outputs the generated image data to a non-illustrated subsequent device as an output signal of the solid-state imaging device 2.

The timing controller 46 generates various kinds of timing signals, clock signals, control signals, and the like. On the basis of the generated signal, the timing controller 46 performs drive control of the row selector 41, the constant-current source 42, the analog-to-digital converter 43, the horizontal transfer scanner 44, the signal processor 45, and the like.

### (4) Configuration of Pixel 30 and Pixel Circuit 5

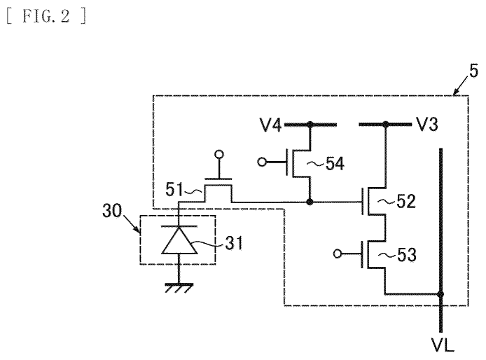

FIG. 2 illustrates an example of the circuit configuration of the pixel 30 and the pixel circuit 5.

The pixel 30 includes a photoelectric conversion element 31. The photoelectric conversion element 31 converts incident light into an electric charge and accumulates the electric charge.

Here, the photoelectric conversion element 31 includes a photodiode. Note that, the photoelectric conversion element 31 may include a plurality of photodiodes. Alternatively, the photoelectric conversion element 31 may include an organic photoelectric conversion layer. Further, the photoelectric conversion element 31 may include a photodiode and an organic photoelectric conversion layer.

Here, the pixel circuit 5 includes a transfer transistor 51, an amplifier transistor 52, a selector transistor 53, and a reset transistor 54.

One of a pair of main electrodes of the transfer transistor 51 is electrically coupled to a cathode electrode of the photoelectric conversion element 31. An anode electrode of the photoelectric conversion element 31 is grounded. The ground is, for example, 0 [V]. Another of the pair of main electrodes of the transfer transistor 51 is electrically coupled to a gate electrode of the amplifier transistor 52 through a floating diffusion FD.

One of a pair of main electrodes of the amplifier transistor 52 is electrically coupled to a power supply line V3. Another of the pair of main electrodes of the amplifier transistor 52 is electrically coupled to one of a pair of main electrodes of the selector transistor 53.

Another of the pair of main electrodes of the selector transistor 53 is electrically coupled to the corresponding one of the signal lines (vertical signal lines) VL.

One of a pair of main electrodes of the reset transistor 54 is electrically coupled to the floating diffusion FD. Another of the pair of main electrodes of the reset transistor 54 is electrically coupled to a power supply line V4.

In the first embodiment, the same voltage is supplied to each of the power supply line V3 and the power supply line V4. The voltage supplied to each of the power supply line V3 and the power supply line V4 is, for example, greater than or equal to 3 [V] and less than or equal to 5 [V].

### (5) Configuration of Inspection System 6

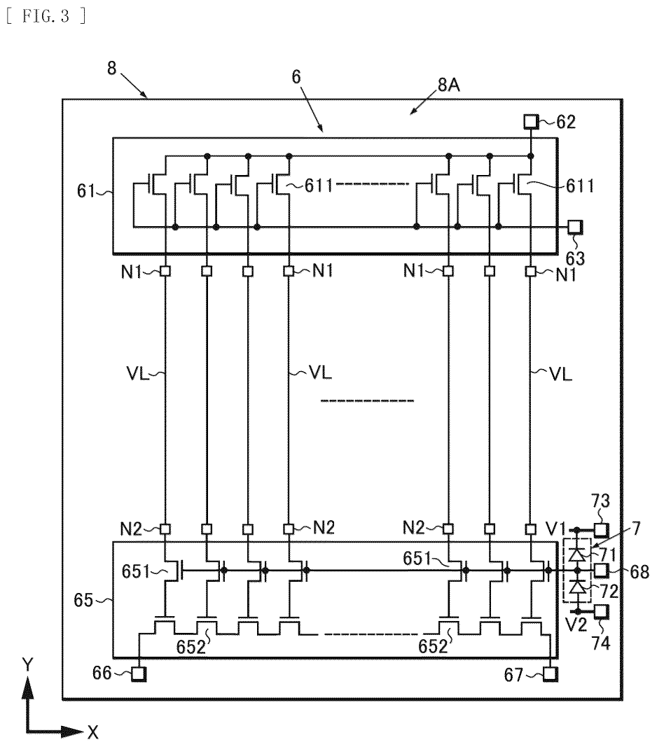

FIG. 3 illustrates an example of a circuit configuration of an inspection system 6 for the signal lines VL.

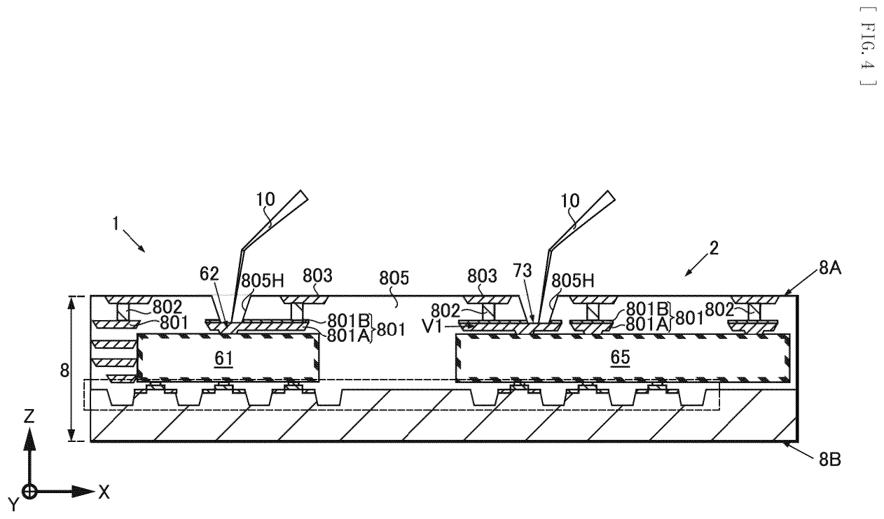

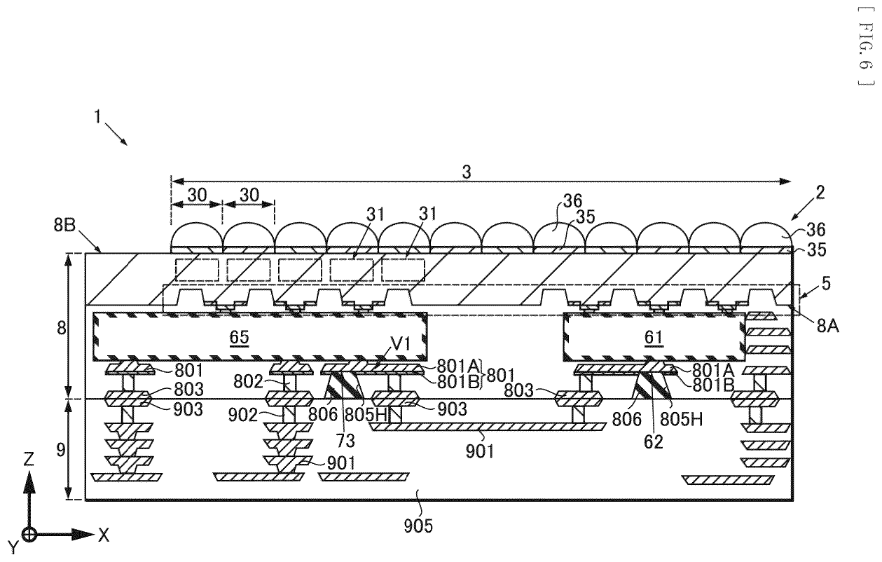

In the first embodiment, the inspection system 6 is disposed on a side of a first surface 8A of a first substrate 8 (see FIGS. 4 and 6). The first substrate 8 is formed based on a semiconductor substrate such as a single-crystal silicon substrate. The pixels 30 and the pixel circuit 5 are disposed on a second surface 8B, of the first substrate S, opposed to the first surface 8A (see FIGS. 4 and 6). Further, a second substrate 9 is bonded to the side of the first surface 8A of the first substrate 8. The above-described peripheral circuit is disposed on the second substrate 9.

A specific configuration of the solid-state imaging device 2 will be described later.

The inspection system 6 includes the signal lines VL, an application circuit 61, a first inspection terminal 62, a first inspection terminal 63, a detection circuit 65, a second inspection terminal 66, a second inspection terminal 67, and a second inspection terminal 68 as main components.

As described above, the signal lines VL are vertical signal lines extending in the arrow-Y direction and are arranged in the arrow-X direction in the pixel region 3. At one end of each of the signal lines VL in an extending direction, a node region N1 is disposed for each signal line VL. In addition, at another end of each of the signal lines VL in the extending direction, a node region N2 is disposed for each signal line VL.

Each of the node region N1 and the node region N2 is electrically coupled to the peripheral circuit at a stage where the second substrate 9 is bonded to the first substrate 8.

The application circuit 61 is electrically coupled to one end of each of the signal lines VL. The application circuit 61 includes, as current sources, a plurality of IGFETs 611 disposed for each respective signal line VL. One of a pair of main electrodes of each of the IGFETs 611 is electrically coupled to the respective signal line VL. Another of the pair of main electrodes of each of the IGFETs 611 is electrically coupled to the first inspection terminal 62 disposed adjacent to the application circuit 61. The first inspection terminal 62 is shared by the plurality of IGFETs. An inspection signal is supplied to the first inspection terminal 62.

Further, a gate electrode of each of the IGFETs 611 is electrically coupled to the first inspection terminal 63. The first inspection terminal 63 is disposed adjacent to the application circuit 61 and is shared by the plurality of IGFETs 611. A control signal that controls a current supply operation of the application circuit 61 is supplied to the first inspection terminal 63 in the inspection step.

The detection circuit 65 is electrically coupled to the other ends of the plurality of signal lines VL. The detection circuit 65 includes IGFETs 651 each disposed for the respective signal line VL and IGFETs 652 each disposed for the respective signal line VL. The detection circuit 65 is constructed as an open type detection circuit that detects a disconnection defect of any of the signal lines VL.

One of a pair of main electrodes of each of the IGFETs 651 is electrically coupled to the respective signal line VL. Another of the pair of main electrodes of each of the IGFETs 651 is electrically coupled to a gate electrode of the respective IGFET 652.

Further, a gate electrode of each of the IGFETs 651 is electrically coupled to the second inspection terminal 68. The second inspection terminal 68 is disposed adjacent to the detection circuit 65 and is shared by the plurality of IGFETs 651. In the inspection step, a control signal that controls a detection operation of the detection circuit 65 is supplied to the second inspection terminal 68.

One of a pair of main electrodes of each of the IGFETs 652 is electrically coupled to another of the pair of main electrodes of another IGFET 652 that is adjacent. The other of the pair of main electrodes of each of the IGFETs 652 is electrically coupled to the one of the pair of main electrodes of another IGFET 652 that is adjacent. That is, the plurality of IGFETs 652 disposed for each respective signal line VL is electrically coupled in series.

The one of the pair of main electrodes of the IGFET 652 at an end of the IGFETs 652 electrically coupled in series is electrically coupled to the second inspection terminal 66. The other of the pair of main electrodes of the IGFET 652 at another end of the IGFETs 652 electrically coupled in series is electrically coupled to the second inspection terminal 67.

A detection signal that detects a good or bad status of the signal lines VL is supplied to the second inspection terminal 66. In contrast, a detection result is outputted to the second inspection terminal 67.

In addition, at least one of the first inspection terminal 62 and the first inspection terminal 63 may be disposed in a region that is assumed to be within the application circuit 61.

Similarly, at least one of the second inspection terminal 66, the second inspection terminal 67, and the second inspection terminal 68 may be disposed in a region that is assumed to be within the detection circuit 65.

### (6) Configuration of Protection Element 7

A protection element 7 is disposed in the above-described inspection system 6. Details will be described.

In the first embodiment, the protection element 7 is electrically coupled to the second inspection terminal 68. More specifically, the protection element 7 is interposed between the gate electrodes of the IGFETs 651 of the detection circuit 65 and the second inspection terminal 68.

The protection element 7 includes a first protection element 71 and a second protection element 72. The first protection element 71 includes a protection diode. An anode electrode of the first protection element 71 is electrically coupled to the second inspection terminal 68. A cathode electrode of the first protection element 71 is electrically coupled to a first power supply line V1. That is, the first protection element 71 is electrically coupled in parallel between the gate electrodes of the IGFETs 651 and the second inspection terminal 68.

The first power supply line V1 is electrically coupled to a third inspection terminal 73. The first power supply line V1 and the third inspection terminal 73 are disposed on the first substrate 8 in the inspection step, and are electrically isolated from the first inspection terminal 62 because the second substrate 9 is not bonded. That is, an inspection signal supplied to the first inspection terminal 62 and power supplied to the first power supply line V1 through the third inspection terminal 73 are each supplied independently.

When the second substrate 9 is bonded to the first substrate 8 after the inspection step, and the solid-state imaging device 2 is completed as a final product, the first inspection terminal 62 and the first power supply line V1 are electrically coupled to each other.

The voltage supplied to the third inspection terminal 73 is, for example, greater than or equal to 3 [V] and less than or equal to 5 [V].

The first protection element 71 defines an upper limit of a surge and absorbs a surge exceeding the upper limit.

Similarly to the first protection element 71, the second protection element 72 includes a protection diode. A cathode electrode of the second protection element 72 is electrically coupled to the second inspection terminal 68. An anode electrode of the second protection element 72 is electrically coupled to a second power supply line V2. That is, the second protection element 72 is electrically coupled in parallel between the gate electrodes of the IGFETs 651 and the second inspection terminal 68.

The second power supply line V2 is electrically coupled to a third inspection terminal 74. In the inspection step, the second power supply line V2 and the third inspection terminal 74 may be independent from a power supply terminal (not illustrated) of the peripheral circuit, similarly to the first power supply line V1 and the third inspection terminal 73. Alternatively, the second power supply line V2 and the third inspection terminal 74 may be non-independent from the power supply terminal (not illustrated) of the peripheral circuit.

The voltage supplied to the third inspection terminal 74 is, for example, 0 [V].

The second protection element 72 defines a lower limit of a surge and absorbs a surge below the lower limit.

### (7) Longitudinal Sectional Configuration of Solid-State Imaging Device 2 in Inspection Step and Circuit Configuration of Inspection System 6

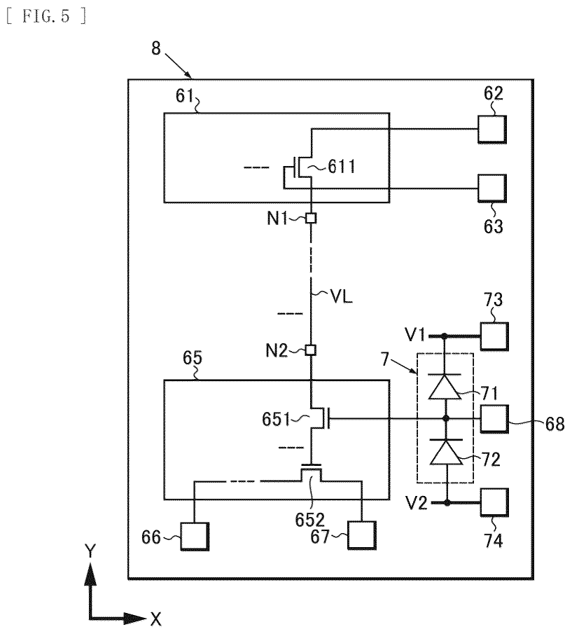

FIG. 4 illustrates an example of a main part of the first substrate 8 illustrating the inspection step of the signal lines VL in the manufacturing process of the solid-state imaging device 2. FIG. 5 illustrates an example of a schematic circuit configuration of the inspection system 6 in the inspection step of the signal lines VL.

In the inspection step of the solid-state imaging device 2, although illustrated in a simplified manner in FIG. 4, the application circuit 61 and the detection circuit 65 are disposed in the first substrate 8. The inspection step is what is called a probe inspection step. In an open type inspection step, a disconnection defect of the signal lines VL is detected.

A plurality of layers of a wiring 801 and a wiring 803 are disposed on the side of the first surface 8A of the first substrate 8. The wiring 801 is formed by stacking a wiring 801A including, for example, copper (Cu) and a barrier metal film 801B disposed on the surface of the wiring 801A. As the barrier metal film 801B, for example, a metallic material such as tungsten (W) or titanium-tungsten (TiW) is used. The wiring 803 includes, for example, a wiring material such as copper (Cu).

Further, the wiring 801 and the wiring 803 are electrically coupled to each other by a plug wiring 802. The plug wiring 802 includes, for example, a metal material such as tungsten (W).

The wiring 801, the plug wiring 802, and the wiring 803 are disposed in an insulator 805. The insulator 805 is actually formed by stacking a plurality of insulating films such as silicon oxide (SiO₂) and silicon nitride (SiN). The insulator 805 corresponds to a “first insulator” according to the present technology.

The first inspection terminal 62, the first inspection terminal 63, the second inspection terminal 66, the second inspection terminal 67, the second inspection terminal 68, the third inspection terminal 73, and the third inspection terminal 74 of the inspection system 6 illustrated in FIGS. 3 to 5 are formed using the wiring 801. Here, the wording “formed using the wiring 801” is used in a sense that the first inspection terminal 62 and the like are formed in the same manufacturing process as the process of forming the wiring 801. Although only the sections of the first inspection terminal 62 and the third inspection terminal 73 are illustrated in FIG. 4, other first inspection terminal 63 and the like have similar sectional configurations.

In addition, the first inspection terminal 62 and the like are formed to have a wider wiring width than the wiring width of the wiring 801 and the like.

Surfaces of the first inspection terminal 62, the second inspection terminal 68, and the like are exposed through a respective inspection opening 805H formed in the insulator 805. In the inspection opening 805H, the barrier metal film 801B on each of the surfaces of the first inspection terminal 62, the second inspection terminal 68, and the like is removed.

As illustrated in FIG. 4, a probe needle 10 is brought into contact with the surface of each of the first inspection terminal 62, the second inspection terminal 68, and the like, and a disconnection defect of the signal lines VL is detected by the open type inspection step. A specific detection method will be described later.

In the inspection step, because the protection element 7 is disposed in the inspection system 6, when a surge occurs, the surge is absorbed by the protection element 7. This makes it possible to improve an electrostatic breakdown voltage in the inspection step, and thus makes it possible to improve a manufacturing yield of the solid-state imaging device 2.

Further, in the inspection step, the first inspection terminal 62 positioned close to the application circuit 61 and the first power supply line V1 (the third inspection terminal 73) coupled to the protection element 7, in particular, are electrically separated from each other in the first substrate 8. It is thus possible for the first inspection terminal 62 and the first power supply line V1 (the third inspection terminal 73) to independently supply an inspection signal and power, respectively. This makes it possible to perform the inspection step in which the inspection signal supplied to the first inspection terminal 62 is changed (for example, in which the voltage is changed).

Further, because the barrier metal film 801B is not formed on the surface of the first inspection terminal 62 or the like, it is possible to reduce contact resistance between the surface of the first inspection terminal 62 or the like and the probe needle 10. In addition, a needle mark caused by the contact of the probe needle 10 remains on the surface of the first inspection terminal 60 or the like.

### (8) Longitudinal Sectional Configuration of Solid-State Imaging Device 2 as Final Product and Circuit Configuration of Inspection System 6

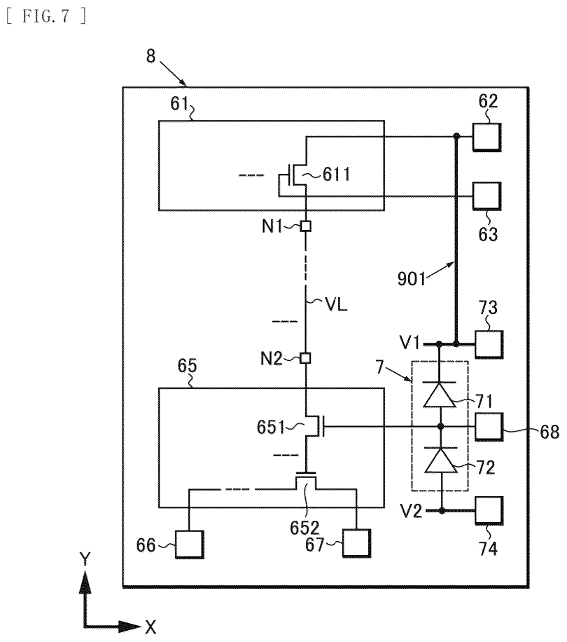

FIG. 6 illustrates an example of a main part of the solid-state imaging device 2 as a final product. FIG. 7 illustrates an example of a schematic circuit configuration of the inspection system 6 in the solid-state imaging device 2 illustrated in FIG. 6.

As illustrated in FIG. 6, the solid-state imaging device 2 is constructed by bonding the second substrate 9 to the side of the first surface SA of the first substrate 8.

Here, the pixel circuit 5 and the pixels 30 are each sequentially disposed on a side of the second surface 8B of the first substrate 8. Each of the pixels 30 includes the photoelectric conversion element 31, an optical filter 35, and an optical lens 36 sequentially stacked on one another.

The optical filter 35 includes, for example, a total of three color filters having different colors for each pixel 30. That is, the optical filter 35 includes a red light filter that transmits light in a red light band, a green light filter that transmits light in a green light band, and a blue light filter that transmits light in a blue light band. The optical filter 35 includes, for example, a resin material including a dye.

The optical lens 36 is formed in a curved shape that curves toward a light incident side and condenses the incident light in the photoelectric conversion element 31. The optical lens 36 is formed as what is called an on-chip lens and is formed for each pixel 30 or integrally over the plurality of pixels 30. The optical lens 36 includes, for example, a transparent resin material.

As described above, the second substrate 9 includes the semiconductor substrate and the peripheral circuit, the detailed description of the configuration of which will be omitted, and further includes a wiring 901, a plug wiring 902, a wiring 903, and the like. Each of the wiring 901, the plug wiring 902, and the wiring 903 includes, for example, the same material as each of the wiring 801, the plug wiring 802, and the wiring 803. Further, the wiring 901 and the like are disposed in an insulator 905.

At the time of bonding the second substrate 9, the inspection opening 805H of the first substrate 8 is filled with a buried insulator 806. The buried insulator 806 corresponds to a “second insulator” according to the present technology. The wiring 803 of an uppermost layer of the first substrate 8 and the wiring 903 of an uppermost layer of the second substrate 9 are joined to each other to bond the second substrate 9 to the first substrate 8. Accordingly, the solid-state imaging device 2 is constructed. The joining includes, for example, a Cu—Cu bonding.

Here, as illustrated in FIGS. 6 and 7, when the second substrate 9 is bonded to the first substrate 8, the first inspection terminal 62 of the inspection system 6 of the first substrate 8 and the first power supply line V1 are electrically coupled to each other using the wiring 901 of the second substrate 9.

### Inspection Method of Signal Lines VL

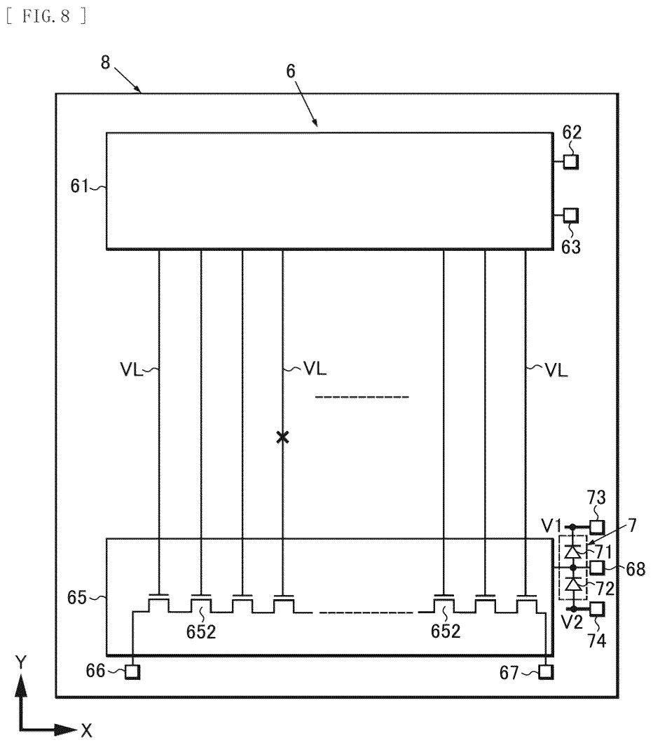

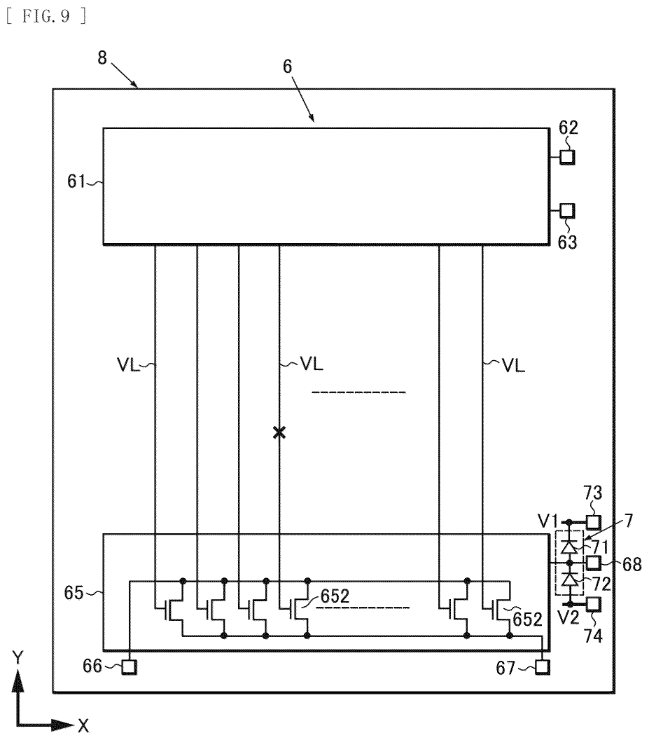

Next, an inspection method using the above-described inspection system 6 will be briefly described with reference to FIGS. 8 and 9.

### (1) Inspection Method in First Inspection Mode

FIG. 8 illustrates an example of a schematic circuit configuration that describes a first inspection mode.

In the first inspection mode illustrated in FIG. 8, the detection circuit 65 of the inspection system 6 includes the circuit described above. That is, the detection circuit 65 includes an AND circuit.

First, a low-level signal (hereinafter, simply referred to as “L signal”) is supplied to the first inspection terminal 62 as the inspection signal. Subsequently, a high-level signal (hereinafter, simply referred to as “H signal”) is supplied to the first inspection terminal 63 as the control signal. This causes all the signal lines VL to be reset to the L signal.

Thereafter, the H signal is supplied to the first inspection terminal 62, and the H signal is supplied to the first inspection terminal 63. This causes all the signal lines VL to become the H signal.

In the detection circuit 65, the H signal is supplied to the second inspection terminal 68 as the control signal. Subsequently, the H signal is supplied to the second inspection terminal 66 as the detection signal. As a result, each of the IGFETs 651 and each of the IGFETs 652 are brought into an on-state, and the detection signal supplied to the second inspection terminal 66 is detected at the second inspection terminal 67. When no disconnection defect exists in all of the signal lines VL, the detection signal detected at the second inspection terminal 67 becomes equal to the detection signal supplied to the second inspection terminal 66.

Here, as indicated by a mark “x” in FIG. 8, when a disconnection defect occurs in one of the signal lines VL, the IGFET 652 coupled to this signal line VL is brought into an off-state. The detection signal supplied to the second inspection terminal 66 is thus not detected at the second inspection terminal 67.

### (2) Inspection Method in Second Inspection Mode

FIG. 9 illustrates an example of a schematic circuit configuration that describes a second inspection mode.

In the second inspection mode illustrated in FIG. 9, the detection circuit 65 of the inspection system 6 includes an OR circuit. That is, the IGFETs 652 are electrically coupled in parallel between the second inspection terminal 66 and the second inspection terminal 67.

First, the H signal is supplied to the first inspection terminal 62 as the inspection signal, and the H signal is supplied to the first inspection terminal 63 as the control signal. This causes all the signal lines VL to be reset to the H signal.

Thereafter, the L signal is supplied to the first inspection terminal 63, and the first inspection terminal 62 is thus disconnected from the signal lines VL.

In the detection circuit 65, the H signal is supplied to the second inspection terminal 68 as the control signal. Subsequently, the H signal is supplied to the second inspection terminal 66 as the detection signal. As a result, the IGFETs 651 are brought into the on-state, and the IGFETs 652 are brought into the off-state. When there is no disconnection defect in all of the signal lines VL, no detection signal is detected at the second inspection terminal 67.

Here, as indicated by a mark “x” in FIG. 9, when a disconnection defect occurs in one of the signal lines VL, the IGFET 652 coupled to this signal line VL is brought into the on-state. The detection signal supplied to the second inspection terminal 66 is thus detected at the second inspection terminal 67.

### Workings and Effects

As illustrated in FIGS. 3, 5, and 7, the semiconductor device 1 according to the first embodiment includes the signal lines VL, the application circuit 61, the first inspection terminal 62, the detection circuit 65, and the second inspection terminal 68.

The plurality of signal lines VL extends in the first direction and is arranged in the second direction that intersects the first direction. The application circuit 61 is electrically coupled to one end of each of the signal lines VL and supplies the inspection signal to each of the signal lines VL. The first inspection terminal 62 supplies the inspection signal to the application circuit 61. The detection circuit 65 is electrically coupled to the other end of each of the signal lines VL and detects a defect in any of the signal lines VL. The second inspection terminal 68 supplies the control signal that controls the detection operation of the detection circuit 65.

Here, the semiconductor device I further includes the protection element 7. The protection element 7 is electrically coupled to the second inspection terminal 68 and absorbs a surge.

Accordingly, the surge is absorbed by the protection element 7 in the inspection step, and it is thus possible to provide the semiconductor device 1 that makes it possible to improve the electrostatic breakdown voltage. In the first embodiment, the solid-state imaging device 2 is mounted on the semiconductor device 1, and it is thus possible to provide the solid-state imaging device 2 that makes it possible to improve the electrostatic breakdown voltage.

In other words, it is possible to provide the semiconductor device 1 or the solid-state imaging device 2 that makes it possible to reduce the manufacturing yield.

In detail, the protection element 7 is electrically coupled between the second inspection terminal 68 and the power supply line. More specifically, the detection circuit 65 includes the IGFETs 651 in each of which one of the pair of main electrodes is electrically coupled to the other end of the respective signal line VL and the gate electrode is electrically coupled to the second inspection terminal 68. The protection element 7 is electrically coupled in parallel between the second inspection terminal 68 and the gate electrodes.

The power supply line includes the first power supply line V1 and the second power supply line V2. The second power supply line V2 is supplied with a power lower than the power supplied to the first power supply line V1. The protection element 7 includes the first protection element 71 electrically coupled between the second inspection terminal 68 and the first power supply line V1, and the second protection element 72 electrically coupled between the second inspection terminal 68 and the second power supply line V2. The protection element 7 includes a protection diode.

In the semiconductor device 1 configured as described above, it is possible to reliably absorb both positive and negative surges by the first protection element 71 and the second protection element 72 in the inspection step, and it is thus possible to further improve the electrostatic breakdown voltage.

In addition, in the semiconductor device 1, the signal lines VL, the application circuit 61, the first inspection terminal 62, the detection circuit 65, the second inspection terminal 68, and the protection element 7 are disposed on the side of the first surface 8A of the first substrate 8 as illustrated in FIGS. 3, 4, and 6. In the first substrate 8, the first inspection terminal 62 and the power supply line (the first power supply line V1) are electrically isolated from each other, and the inspection signal and the power are each supplied independently.

Accordingly, in the inspection step, it is possible to supply, to the first inspection terminal 62, the inspection signal of different levels with respect to the power supplied to the power supply line. This makes it possible to improve the degree of freedom of inspection. Specifically, it is possible to perform the inspection step on the power supplied to the first power supply line V1 using the inspection signal having the same voltage level, a low voltage level, or a high voltage level.

### 2. Second Embodiment

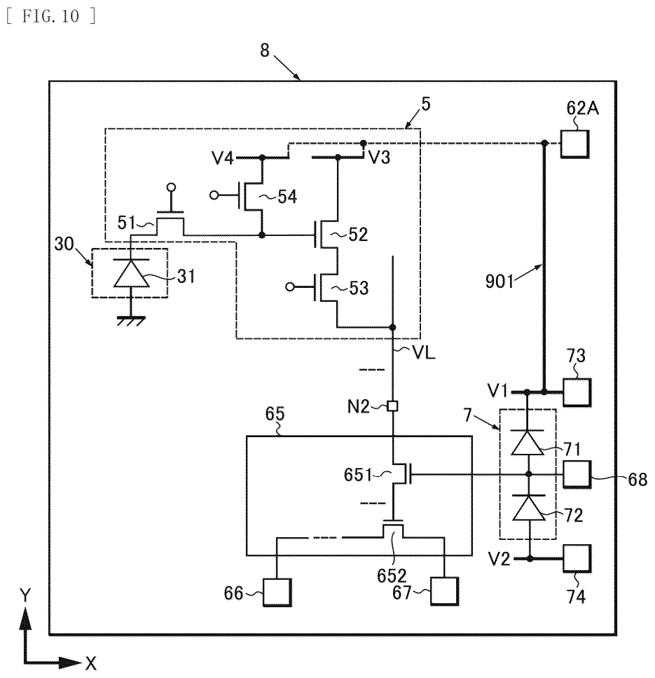

The semiconductor device 1 according to a second embodiment of the present disclosure will be described with reference to FIG. 10.

In addition, in the second embodiment and the subsequent embodiments, the same components or substantially the same components as those of the semiconductor device 1 according to the first embodiment are denoted by the same reference numerals, and redundant descriptions thereof will be omitted.

### Configuration of Inspection System 6

FIG. 10 illustrates an example of a schematic circuit configuration of the inspection system 6 of the solid-state imaging device 2 mounted on the semiconductor device 1.

In the inspection system 6 according to the second embodiment, the application circuit 61 is omitted in the inspection system 6 according to the first embodiment. Details will be described.

As described above, the pixel circuit 5 is disposed on the first substrate 8. The pixel circuit 5 is provided with a power supply line V3 and a power supply line V4. In the second embodiment, the same power is supplied to the power supply line V3 and the power supply line V4.

On the first surface 8A of the first substrate 8, although an arrangement location is not particularly limited, a power supply terminal 62A electrically coupled to the power supply line V3 and the power supply line V4 is disposed in a peripheral part. In the second embodiment, the power supply terminal 62A is used as the first inspection terminal 62 according to the first embodiment in the inspection step.

In a particular pixel circuit 5, the power supply line V3 is electrically coupled to the corresponding one of the signal lines VL with the amplifier transistor 52 and the selector transistor 53 interposed therebetween. The power supply line V4 is electrically coupled to the gate electrode of the amplifier transistor 52 with the reset transistor 54 interposed therebetween. That is, it is possible to use the pixel circuit 5 as the application circuit 61 and supply the inspection signal to the signal line VL by controlling the amplifier transistor 52, the selector transistor 53, and the reset transistor 54 to be in the on-state.

The inspection system 6 configured as described above makes it possible to omit the application circuit 61. After the inspection step, the second substrate 9 is bonded to the first substrate 8, causing the power supply terminal 62A and the first power supply line V1 of the protection element 7 to be electrically coupled to each other using the wiring 901 of the second substrate 9.

Because the components other than the above are the same components or substantially the same components as those of the semiconductor device I according to the first embodiment, the description thereof will be omitted.

### Workings and Effects

According to the semiconductor device 1 of the second embodiment, it is possible to obtain the same workings and effects as those obtainable by the semiconductor device 1 of the first embodiment.

In addition, in the semiconductor device 1, it is possible to use the particular pixel circuit 5 of the solid-state imaging device 2 as the application circuit 61 according to the first embodiment, as illustrated in FIG. 10. This makes it possible to effectively use the first substrate 8 by a portion corresponding to the application circuit 61 and to improve the integration degree of the semiconductor device I and the solid-state imaging device 2.

### 3. Third Embodiment

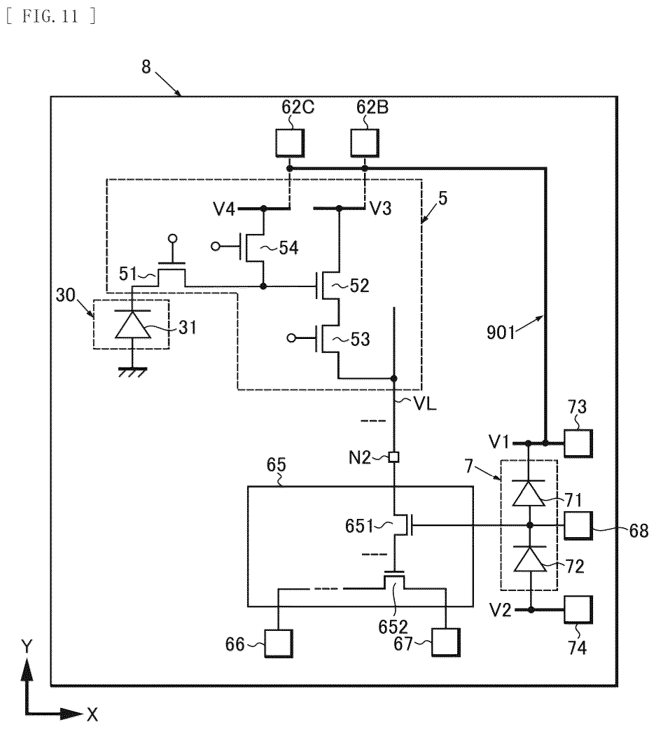

The semiconductor device 1 according to a third embodiment of the present disclosure will be described with reference to FIG. 11.

### Configuration of Inspection System 6

FIG. 11 illustrates an example of a schematic circuit configuration of the inspection system 6 of the solid-state imaging device 2 mounted on the semiconductor device 1.

In the inspection system 6 according to the third embodiment, the application circuit 61 is omitted similarly to the inspection system 6 according to the second embodiment. Details will be described.

As described above, the pixel circuit 5 is disposed on the first substrate 8. The pixel circuit 5 is provided with the power supply line V3 and the power supply line V4. In the third embodiment, the power supply line V3 and the power supply line V4 are electrically isolated from each other. That is, the power supplied to the power supply line V4 is supplied independently from the power supplied to the power supply line V3.

On the first surface 8A of the first substrate 8, although the arrangement location is not particularly limited, a power supply terminal 62B electrically coupled to the power supply line V3 is disposed in the peripheral part, and a power supply terminal 62C electrically coupled to the power supply line V4 is further disposed. In the third embodiment, for example, the power supply terminal 62B is used as the first inspection terminal 62 according to the first embodiment in the inspection step, and the power supply terminal 62C is used as the first inspection terminal 63 according to the first embodiment in the inspection step.

In a particular pixel circuit 5, the power supply line V3 is electrically coupled to the corresponding one of the signal lines VL with the amplifier transistor 52 and the selector transistor 53 interposed therebetween. The power supply line V4 is electrically coupled to the gate electrode of the amplifier transistor 52 with the reset transistor 54 interposed therebetween. That is, it is possible to use the pixel circuit 5 as the application circuit 61 and supply the inspection signal to the signal line VL by controlling the amplifier transistor 52, the selector transistor 53, and the reset transistor 54 to be in the on-state.

The inspection system 6 configured as described above makes it possible to omit the application circuit 61. After the inspection step, the second substrate 9 is bonded to the first substrate 8, causing the power supply terminal 62B and the power supply terminal 62C to be each electrically coupled to the first power supply line V1 of the protection element 7 using the wiring 901 of the second substrate 9.

Because the components other than the above are the same components or substantially the same components as those of the semiconductor device 1 according to the second embodiment, the description thereof will be omitted.

### Workings and Effects

According to the semiconductor device 1 of the third embodiment, it is possible to obtain the same workings and effects as those obtainable by the semiconductor device 1 of the second embodiment.

In addition, in the semiconductor device 1, it is possible to independently supply power to each of the power supply terminal 62B and the power supply terminal 62C in the inspection step as illustrated in FIG. 11. It is thus possible to easily adjust the timing of supplying the inspection signal to the signal lines VL.

### 4. Fourth Embodiment

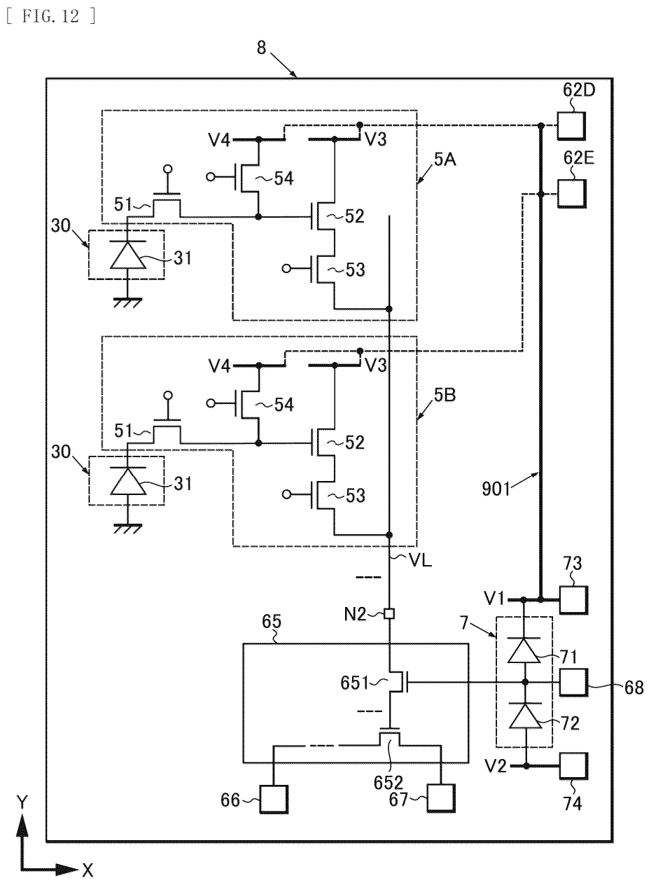

The semiconductor device 1 according to a fourth embodiment of the present disclosure will be described with reference to FIG. 12.

### Configuration of Inspection System 6

FIG. 12 illustrates an example of a schematic circuit configuration of the inspection system 6 of the solid-state imaging device 2 mounted on the semiconductor device 1.

The inspection system 6 according to the fourth embodiment is an application example of the inspection system 6 according to the second embodiment, and the application circuit 61 is similarly omitted. Details will be described.

The pixel circuit 5 is disposed on the first substrate 8. The pixel circuit 5 is provided with the power supply line V3 and the power supply line V4. In the fourth embodiment, the same power is supplied to the power supply line V3 and the power supply line V4.

On the first surface 8A of the first substrate 8, although an arrangement location is not particularly limited, a power supply terminal 62D electrically coupled to the power supply line V3 and the power supply line V4 of a particular pixel circuit 5A is disposed in the peripheral part. The pixel circuit 5A is disposed on a row-by-row basis, and is disposed, for example, in a middle portion of the pixel region 3.

Further, a power supply terminal 62E electrically coupled to the power supply line V3 and the power supply line V4 of another particular pixel circuit 5B is disposed. The pixel circuit 5B is disposed by row other than the row having the pixel circuit 5A.

In the fourth embodiment, the power supply terminal 62D and the power supply terminal 62E are used as the first inspection terminal 62 according to the first embodiment in the inspection step.

The inspection system 6 configured as described above makes it possible to omit the application circuit 61. After the inspection step, the second substrate 9 is bonded to the first substrate 8, causing the power supply terminal 62D and the power supply terminal 62E to be each electrically coupled to the first power supply line V1 of the protection element 7 using the wiring 901 of the second substrate 9.

Because the components other than the above are the same components or substantially the same components as those of the semiconductor device 1 according to the second embodiment, the description thereof will be omitted.

### Workings and Effects

According to the semiconductor device 1 of the fourth embodiment, it is possible to obtain the same workings and effects as those obtainable by the semiconductor device 1 of the second embodiment.

In addition, in the semiconductor device 1, it is possible to independently supply power to each of the power supply terminal 62D and the power supply terminal 62E in the inspection step as illustrated in FIG. 12. This makes it possible to independently execute at least one of the inspection step by row including the pixel circuit 5A or the inspection step by row including the pixel circuit 5B. As a result, it is possible to broaden the range of the inspection method.

### 5. Fifth Embodiment

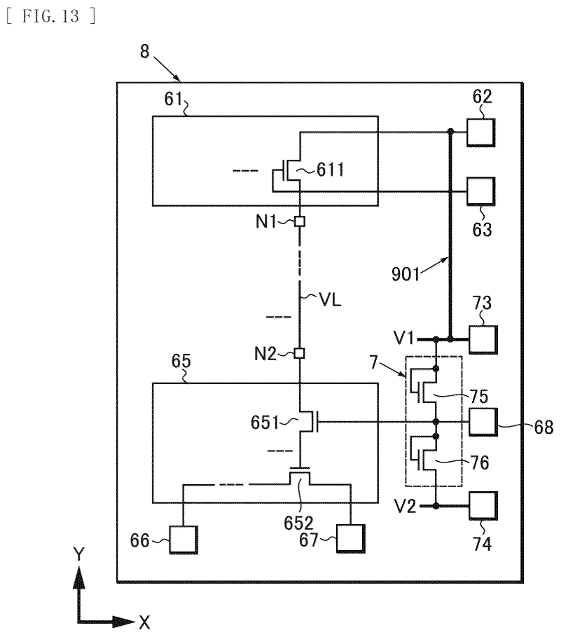

The semiconductor device I according to a fifth embodiment of the present disclosure will be described with reference to FIG. 13.

### Configuration of Inspection System 6

FIG. 13 illustrates an example of a schematic circuit configuration of the inspection system 6 of the solid-state imaging device 2 mounted on the semiconductor device 1.

In the inspection system 6 according to the fifth embodiment, the configuration of the protection element 7 of the inspection system 6 according to the first embodiment is changed. Details will be described.

The protection element 7 includes a first protection element 75 and a second protection element 76.

The first protection element 75 includes a protection transistor. Specifically, the first protection element 75 includes, for example, a GGMOS (Gate-Grounded Metal-Oxide Semiconductor). One of a pair of main electrodes of the first protection element 75 is electrically coupled to the second inspection terminal 68, and another of the pair of main electrodes is electrically coupled to the first power supply line V1. A gate electrode is electrically coupled to the first power supply line V1.

The second protection element 76 similarly includes a protection transistor and includes, for example, a GGMOS. One of a pair of main electrodes of the second protection element 76 is electrically coupled to the second inspection terminal 68, and another of the pair of main electrodes is electrically coupled to the second power supply line V2. A gate electrode is electrically coupled to the second inspection terminal 68.

Because the components other than the above are the same components or substantially the same components as those of the semiconductor device 1 according to any of the first to fourth embodiments, the description thereof will be omitted.

### Workings and Effects

According to the semiconductor device 1 of the fifth embodiment, it is possible to obtain the same workings and effects as those obtainable by the semiconductor device 1 of any of the first to fourth embodiments.

In addition, in the semiconductor device 1, the protection element 7 of the inspection system 6 includes the protection transistors as illustrated in FIG. 13. The electrostatic breakdown resistance of a protection transistor is generally higher than the electrostatic breakdown resistance of a protection diode.

It is thus possible to provide the semiconductor device 1 and the solid-state imaging device 2 that make it possible to further improve the electrostatic breakdown voltage.

### 6. Sixth Embodiment

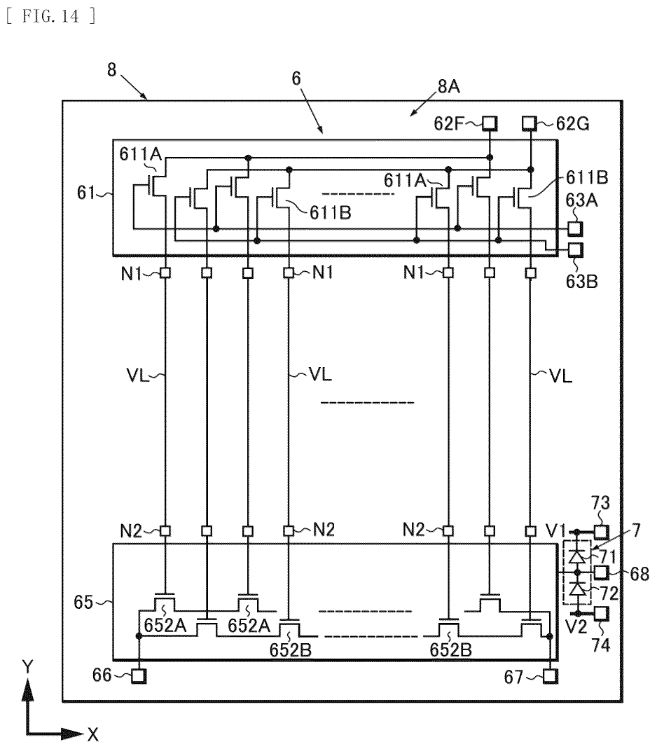

The semiconductor device 1 according to a sixth embodiment of the present disclosure will be described with reference to FIG. 14.

### Configuration of Inspection System 6

FIG. 14 illustrates an example of a schematic circuit configuration of the inspection system 6 of the solid-state imaging device 2 mounted on the semiconductor device 1.

In the inspection system 6 according to the sixth embodiment, both the application circuit 61 and the detection circuit 65 have a two-system circuit configuration in the inspection system 6 according to the first embodiment. Details will be described.

In the application circuit 61, an IGFET 611A coupled to one of the signal lines VL and an IGFET 611B coupled to the signal line VL adjacent in the arrow-X direction (row direction) are repeatedly arranged in the arrow-X direction. The plurality of IGFETs 611A is electrically coupled in parallel, and the plurality of IGFETs 611B is electrically coupled in parallel.

One of main electrodes of each of the IGFETs 611A is electrically coupled to a first inspection terminal 62F. Gate electrodes of the plurality of IGFETs 611A are electrically coupled to a first inspection terminal 63A.

One of main electrodes of each of the IGFETs 611B is electrically coupled to a first inspection terminal 62G. Gate electrodes of the plurality of IGFETs 611B are electrically coupled to a first inspection terminal 63B.

In the detection circuit 65, an IGFET 652A coupled to one of the signal lines VL and an IGFET 652B coupled to the signal line VL adjacent in the arrow-X direction (row direction) are repeatedly arranged in the arrow-X direction. The plurality of IGFETs 652A is electrically coupled in series, and the plurality of IGFETs 652B is electrically coupled in series.

One of main electrodes of the IGFET 652A disposed at one end of the plurality of IGFETs 652A is electrically coupled to the second inspection terminal 66. Another end of the main electrodes of the IGFET 652A disposed at another end of the plurality of IGFETs 652A is electrically coupled to the second inspection terminal 67. One of main electrodes of the IGFET 652B disposed at one end of the plurality of IGFETs 652B is electrically coupled to the second inspection terminal 66. Another end of the main electrodes of the IGFET 652B disposed at another end of the plurality of IGFETs 652B is electrically coupled to the second inspection terminal 67.

Because the components other than the above are the same components or substantially the same components as those of the semiconductor device 1 according to any of the first to fifth embodiments, the description thereof will be omitted.

### Workings and Effects

According to the semiconductor device 1 of the sixth embodiment, it is possible to obtain the same workings and effects as those obtainable by the semiconductor device 1 of the first embodiment or the fifth embodiment.

In addition, in the semiconductor device 1, the application circuit 61 and the detection circuit 65 of the inspection system 6 have the two-system circuit configuration as illustrated in FIG. 14. Although a description of the specific inspection method is omitted, the detection circuit 65 is constructed as an open detection circuit that detects a disconnection defect of any of the signal lines VL, and further as a short-circuit detection circuit that detects a short-circuit defect between adjacent signal lines VL.

This makes it possible to broaden the range of the inspection method.

### 7. Seventh Embodiment

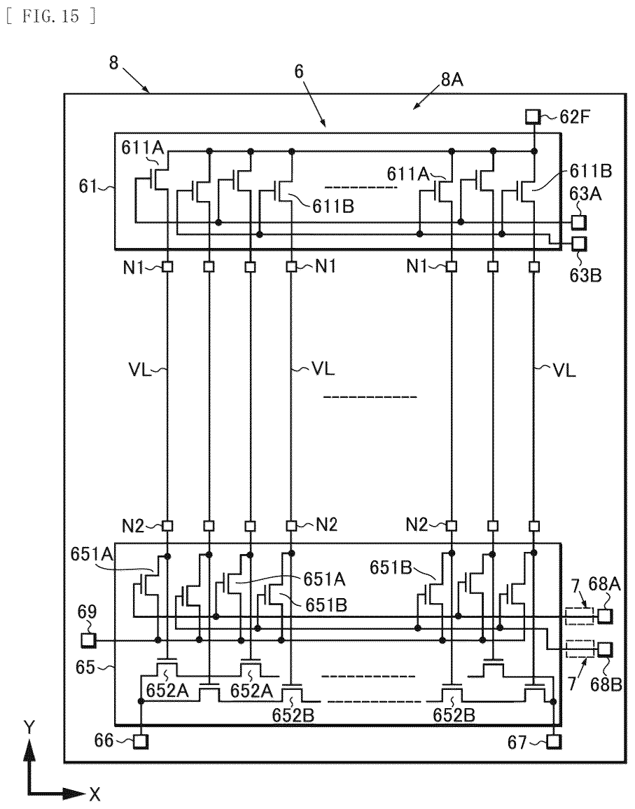

The semiconductor device 1 according to a seventh embodiment of the present disclosure will be described with reference to FIG. 15.

### Configuration of Inspection System 6

FIG. 15 illustrates an example of a schematic circuit configuration of the inspection system 6 of the solid-state imaging device 2 mounted on the semiconductor device 1.

The inspection system 6 according to the seventh embodiment includes the inspection system 6 according to the sixth embodiment with the circuit configurations of the application circuit 61 and the detection circuit 65 being changed. Details will be described.

In the application circuit 61, similarly to the application circuit 61 according to the sixth embodiment, the IGFET 611A and the IGFET 611B are repeatedly arranged in the arrow-X direction. The plurality of IGFETs 611A is electrically coupled in parallel, and the plurality of IGFETs 611B is electrically coupled in parallel. One of main electrodes of each of the IGFETs 611A and one of main electrodes of each of the IGFETs 611B are electrically coupled to the shared first inspection terminal 62F.

The gate electrodes of the plurality of IGFETs 611A are electrically coupled to the first inspection terminal 63A. The gate electrodes of the plurality of IGFETs 611B are electrically coupled to the first inspection terminal 63B.

In the detection circuit 65, similarly to the detection circuit 65 according to the sixth embodiment, the IGFET 652A and the IGFET 652B are repeatedly arranged in the arrow-X direction. The plurality of IGFETs 652A is electrically coupled in series, and the plurality of IGFETs 652B is electrically coupled in series.

One of main electrodes of the IGFET 652A disposed at one end of the plurality of IGFETs 652A is electrically coupled to the second inspection terminal 66. Another of the main electrodes of the IGFET 652A disposed at another end of the plurality of IGFETs 652A is electrically coupled to the second inspection terminal 67. One of main electrodes of the IGFET 652B disposed at one end of the plurality of IGFETs 652B is electrically coupled to the second inspection terminal 66. Another of the main electrodes of the IGFET 652B disposed at another end of the plurality of IGFETs 652B is electrically coupled to the second inspection terminal 67.

In the detection circuit 65, an IGFET 651A coupled to one of the signal lines VL and an IGFET 651B coupled to the signal line VL adjacent in the arrow-X direction (row direction) are further repeatedly arranged in the arrow-X direction. One of main electrodes of each of the IGFETs 651A is electrically coupled to the corresponding one of the signal lines VL. One of main electrodes of each of the IGFETs 651B is electrically coupled to the adjacent signal line VL. Another of the main electrodes of each of the IGFETs 651A and another of the main electrodes of each of the IGFETs 651B are electrically coupled to a second inspection terminal 69. Gate electrodes of the IGFETs 651A are electrically coupled to a second inspection terminal 68A. Gate electrodes of the IGFETs 651B are electrically coupled to a second inspection terminal 68B.

Because the components other than the above are the same components of substantially the same components as those of the semiconductor device 1 according to the sixth embodiment, the description thereof will be omitted.

### Workings and Effects

According to the semiconductor device 1 of the seventh embodiment, it is possible to obtain the same workings and effects as those obtainable by the semiconductor device 1 of the sixth embodiment.

In addition, in the semiconductor device 1, the IGFETs 611A and the IGFETs 611B are coupled to the first inspection terminal 62F in the application circuit 61 of the inspection system 6 as illustrated in FIG. 15. In the detection circuit 65, the IGFETs 651A and the IGFETs 651B are disposed on the signal lines VL, and the IGFETs 651A and the IGFETs 651B are coupled to the second inspection terminal 69.

It is thus possible to detect a short-circuit defect between the adjacent signal lines VL by measuring the current flowing through the first inspection terminal 62F or the second inspection terminal 69. As a result, it is possible to broaden the range of the inspection method.

### 8. Eighth Embodiment

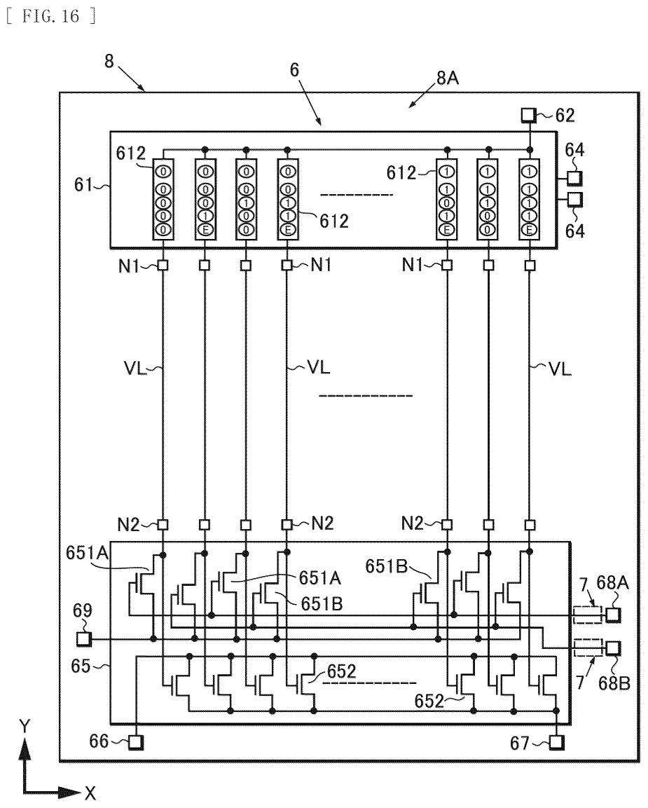

The semiconductor device I according to an eighth embodiment of the present disclosure will be described with reference to FIG. 16.

### Configuration of Inspection System 6

FIG. 16 illustrates an example of a schematic circuit configuration of the inspection system 6 of the solid-state imaging device 2 mounted on the semiconductor device 1.

The inspection system 6 according to the eighth embodiment includes the inspection system 6 according to the seventh embodiment with the circuit configuration of the application circuit 61 being changed. Details will be described.

The application circuit 61 includes a plurality of switch decoders 612 disposed on the signal lines VL. The first inspection terminal 62 that supplies the inspection signal and first inspection terminals 64 that supply the control signal that controls a supply operation are each electrically coupled to the switch decoders 612.

Because the components other than the above are the same components of substantially the same components as those of the semiconductor device 1 according to the seventh embodiment, the description thereof will be omitted.

### Workings and Effects

According to the semiconductor device 1 of the eighth embodiment, it is possible to obtain the same workings and effects as those obtainable by the semiconductor device 1 of the seventh embodiment.

In addition, in the semiconductor device 1, the application circuit 61 of the inspection system 6 includes the switch decoders 612 as illustrated in FIG. 16. It is thus possible to detect a disconnection defect of any of the signal lines VL on a predetermined row-by-row basis. As a result, it is possible to broaden the range of the inspection method.

### 9. Other Embodiments

The present technology is not limited to the above-described embodiments, and may be modified in a variety of ways without departing from the gist thereof.

For example, semiconductor devices according to two or more embodiments may be combined among the semiconductor devices according to the first embodiment to the eighth embodiment described above.

Further, the present technology may be applied to an inspection system for a drive signal line. In this case, the “first direction” according to the present technology is read as the “second direction”, and the “second direction” is read as the “first direction”. Further, the present technology is applicable to a semiconductor device in which three or more substrates are bonded.

Further, the present technology is not limited to the solid-state imaging device, and is widely applicable to a semiconductor device having a plurality of signal lines and having a signal line inspection system.

Furthermore, the present technology may construct the protection element of the inspection system by combining two or more selected from a protection diode, a protection transistor, a protection resistor, and a protection capacitance.

A semiconductor device according to a first embodiment of the present disclosure includes a plurality of signal lines, a first inspection terminal, a detection circuit, and a second inspection terminal.

The plurality of signal lines extends in a first direction and is arranged in a second direction that intersects the first direction. The first inspection terminal is electrically coupled to one end of each of the signal lines and supplies an inspection signal to each of the signal lines. The detection circuit is electrically coupled to another end of each of the signal lines and detects a defect in any of the signal lines. The second inspection terminal supplies a control signal that controls a detection operation of the detection circuit.

Here, the semiconductor device further includes a protection element. The protection element is electrically coupled to the second inspection terminal and absorbs a surge.

Accordingly, the surge is absorbed by the protection element in the inspection step, and it is thus possible to provide the semiconductor device 1 that makes it possible to improve the electrostatic breakdown voltage.

A semiconductor device according to a second embodiment of the present disclosure includes the semiconductor device according to the first embodiment in which the protection element is electrically coupled between the second inspection terminal and a power supply line.

In addition, the signal lines, the first inspection terminal, the detection circuit, the second inspection terminal, and the protection element are disposed on a side of a first surface of a first substrate. In the first substrate, the first inspection terminal and the power supply line are electrically isolated from each other, and the inspection signal and a power are each supplied independently.

Accordingly, in the inspection step, it is possible to supply, to the first inspection terminal, the inspection signal of different levels with respect to the power supplied to the power supply line. This makes it possible to improve the degree of freedom of inspection.

A semiconductor device according to a third embodiment of the present disclosure includes the semiconductor device according to the second embodiment in which a second substrate is bonded to the side of the first surface of the first substrate, and the second substrate includes a wiring that electrically couples the first inspection terminal and the power supply line to each other.

Accordingly, in the inspection step, it is possible to supply, to the first inspection terminal, the inspection signal of different levels with respect to the power supplied to the power supply line. This makes it possible to improve the degree of freedom of inspection.

### Configuration of Present Technology

The present technology has the following configuration. According to the present technology of the following configuration, it is possible to provide a semiconductor device that makes it possible to improve an electrostatic breakdown voltage in an inspection step.
(1)

A semiconductor device including:
a plurality of signal lines extending in a first direction and arranged in a second direction that intersects the first direction;
a first inspection terminal that is electrically coupled to one end of the signal lines and supplies an inspection signal to the signal lines;
a detection circuit that is electrically coupled to another end of the signal lines and detects a defect in the signal lines;
a second inspection terminal that supplies a control signal that controls a detection operation of the detection circuit; and
a protection element that is electrically coupled to the second inspection terminal and absorbs a surge.
(2)

The semiconductor device according to (1), in which the protection element is electrically coupled between the second inspection terminal and a power supply line.
(3)

The semiconductor device according to (2), in which
the detection circuit includes an insulated-gate field-effect transistor including a pair of main electrodes and a gate electrode, one of the main electrodes is electrically coupled to the other end of the signal lines, and the gate electrode is electrically coupled to the second inspection terminal, and
the protection element is electrically coupled in parallel between the second inspection terminal and the gate electrode.
(4)

The semiconductor device according to (2) or (3), in which
the power supply line includes a first power supply line and a second power supply line, a power supplied to the second power supply line is lower than a power supplied to the first power supply line, and
the protection element includes a first protection element and a second protection element, the first protection element is electrically coupled between the second inspection terminal and the first power supply line, and the second protection element is electrically coupled between the second inspection terminal and the second power supply line.
(5)

The semiconductor device according to any one of (2) to (4), in which the protection element includes a protection diode.
(6)

The semiconductor device according to any one of (2) to (4), in which the protection element includes a protection transistor.
(7)

The semiconductor device according to any one of (2) to (6), in which the signal lines, the first inspection terminal, the detection circuit, the second inspection terminal, and the protection element are disposed on a side of a first surface of a first substrate.
(8)

The semiconductor device according to (7), in which, in the first substrate, the first inspection terminal and the power supply line are electrically isolated from each other, and the inspection signal and a power are each supplied independently.
(9)

The semiconductor device according to (8), in which
a first insulator is disposed on the side of the first surface of the first substrate, the first insulator covers the first inspection terminal and the second inspection terminal, and the first insulator has inspection openings through which a surface of the first inspection terminal and a surface of the second inspection terminal are exposed, and
the inspection openings are each filled with a second insulator.
(10)

The semiconductor device according to (8) or (9), in which a second substrate is bonded to the side of the first surface of the first substrate, and the second substrate includes a wiring that electrically couples the first inspection terminal and the power supply line to each other.
(11)

The semiconductor device according to (10), in which
a barrier metal film is disposed on a coupling path between the wiring and the first inspection terminal and between the wiring and the power supply line, and
no barrier metal film is disposed on each of the first inspection terminal and the second inspection terminal.
(12)

The semiconductor device according to (10), in which
a solid-state imaging device is constructed, including:
a pixel disposed on a side of a second surface, of the first substrate, opposite to the side of the first surface, the pixel including a photoelectric conversion element that converts light into an electric charge; and
a pixel circuit that is disposed on the side of the second surface and performs signal processing of the electric charge from the pixel.
(13)

The semiconductor device according to (12), in which
the pixel circuit at least includes
a transfer transistor electrically coupled to the photoelectric conversion element and a floating diffusion,
an amplifier transistor including a gate electrode and a pair of main electrodes, the gate electrode of the amplifier transistor being electrically coupled to the floating diffusion, one of the main electrodes of the amplifier transistor being electrically coupled to a third power supply line,
a reset transistor electrically coupled to the floating diffusion and a fourth power supply line, and
a selector transistor including a pair of main electrodes, one of the main electrodes of the selector transistor being electrically coupled to another of the pair of main electrodes of the amplifier transistor, another of the main electrodes of the selector transistor being electrically coupled to the signal lines.
(14)

The semiconductor device according to (13), in which
in the first substrate, the first inspection terminal is electrically coupled to the third power supply line and the fourth power supply line, and the first inspection terminal and the power supply line are electrically isolated from each other, and
the first inspection terminal and the power supply line are electrically coupled to each other with the wiring of the second substrate being interposed between the first inspection terminal and the power supply line.
(15)

The semiconductor device according to (14), in which, in the first substrate, the third power supply line and the fourth power supply line are electrically isolated from each other and independently supply power.
(16)

The semiconductor device according to (14), in which
the pixel circuit includes a plurality of pixel circuits arranged along the first direction, and
the third power supply line and the fourth power supply line of a part of the plurality of pixel circuits are electrically isolated from the third power supply line and the fourth power supply line of another part of the plurality of pixel circuits in the first substrate.
(17)

The semiconductor device according to any one of (1) to (16), in which a needle mark is formed on a surface of each of the first inspection terminal and the second inspection terminal.
(18)

A semiconductor device including:
a plurality of signal lines extending in a second direction and arranged in a first direction that intersects the second direction;
a first inspection terminal that is electrically coupled to one end of the signal lines and supplies an inspection signal to the signal lines;
a detection circuit that is electrically coupled to another end of the signal lines and detects a defect in the signal lines;
a second inspection terminal that supplies a control signal that controls a detection operation of the detection circuit; and
a protection element that is electrically coupled to the second inspection terminal and absorbs a surge.

The present application claims the benefit of Japanese Priority Patent Application JP2022-187913 filed with the Japan Patent Office on Nov. 25, 2022, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A semiconductor device comprising:
a plurality of signal lines extending in a first direction and arranged in a second direction that intersects the first direction;
a first inspection terminal that is electrically coupled to one end of the signal lines and supplies an inspection signal to the signal lines;
a detection circuit that is electrically coupled to another end of the signal lines and detects a defect in the signal lines;
a second inspection terminal that supplies a control signal that controls a detection operation of the detection circuit; and
a protection element that is electrically coupled to the second inspection terminal and absorbs a surge.

2. The semiconductor device according to claim 1, wherein the protection element is electrically coupled between the second inspection terminal and a power supply line.

3. The semiconductor device according to claim 2, wherein
the detection circuit includes an insulated-gate field-effect transistor including a pair of main electrodes and a gate electrode, one of the main electrodes is electrically coupled to the other end of the signal lines, and the gate electrode is electrically coupled to the second inspection terminal, and
the protection element is electrically coupled in parallel between the second inspection terminal and the gate electrode.

4. The semiconductor device according to claim 2, wherein
the power supply line includes a first power supply line and a second power supply line, a power supplied to the second power supply line is lower than a power supplied to the first power supply line, and
the protection element includes a first protection element and a second protection element, the first protection element is electrically coupled between the second inspection terminal and the first power supply line, and the second protection element is electrically coupled between the second inspection terminal and the second power supply line.

5. The semiconductor device according to claim 1, wherein the protection element includes a protection diode.

6. The semiconductor device according to claim 1, wherein the protection element includes a protection transistor

7. The semiconductor device according to claim 2, wherein the signal lines, the first inspection terminal, the detection circuit, the second inspection terminal, and the protection element are disposed on a side of a first surface of a first substrate.

8. The semiconductor device according to claim 7, wherein, in the first substrate, the first inspection terminal and the power supply line are electrically isolated from each other, and the inspection signal and a power are each supplied independently.

9. The semiconductor device according to claim 8, wherein
a first insulator is disposed on the side of the first surface of the first substrate, the first insulator covers the first inspection terminal and the second inspection terminal, and the first insulator has inspection openings through which a surface of the first inspection terminal and a surface of the second inspection terminal are exposed, and
the inspection openings are each filled with a second insulator.

10. The semiconductor device according to claim 8, wherein a second substrate is bonded to the side of the first surface of the first substrate, and the second substrate includes a wiring that electrically couples the first inspection terminal and the power supply line to each other.

11. The semiconductor device according to claim 10, wherein
a barrier metal film is disposed on a coupling path between the wiring and the first inspection terminal and between the wiring and the power supply line, and
no barrier metal film is disposed on each of the first inspection terminal and the second inspection terminal.

12. The semiconductor device according to claim 10, wherein
a solid-state imaging device is constructed, comprising:
a pixel disposed on a side of a second surface, of the first substrate, opposite to the side of the first surface, the pixel including a photoelectric conversion element that converts light into an electric charge; and
a pixel circuit that is disposed on the side of the second surface and performs signal processing of the electric charge from the pixel.

13. The semiconductor device according to claim 12, wherein
the pixel circuit at least comprises
a transfer transistor electrically coupled to the photoelectric conversion element and a floating diffusion,
an amplifier transistor including a gate electrode and a pair of main electrodes, the gate electrode of the amplifier transistor being electrically coupled to the floating diffusion, one of the main electrodes of the amplifier transistor being electrically coupled to a third power supply line,
a reset transistor electrically coupled to the floating diffusion and a fourth power supply line, and
a selector transistor including a pair of main electrodes, one of the main electrodes of the selector transistor being electrically coupled to another of the pair of main electrodes of the amplifier transistor, another of the main electrodes of the selector transistor being electrically coupled to the signal lines.

14. The semiconductor device according to claim 13, wherein
in the first substrate, the first inspection terminal is electrically coupled to the third power supply line and the fourth power supply line, and the first inspection terminal and the power supply line are electrically isolated from each other, and
the first inspection terminal and the power supply line are electrically coupled to each other with the wiring of the second substrate being interposed between the first inspection terminal and the power supply line.

15. The semiconductor device according to claim 14, wherein, in the first substrate, the third power supply line and the fourth power supply line are electrically isolated from each other and independently supply power.

16. The semiconductor device according to claim 14, wherein
the pixel circuit includes a plurality of pixel circuits arranged along the first direction, and
the third power supply line and the fourth power supply line of a part of the plurality of pixel circuits are electrically isolated from the third power supply line and the fourth power supply line of another part of the plurality of pixel circuits in the first substrate.

17. The semiconductor device according to claim 1, wherein a needle mark is formed on a surface of each of the first inspection terminal and the second inspection terminal.

18. A semiconductor device comprising:
a plurality of signal lines extending in a second direction and arranged in a first direction that intersects the second direction;
a first inspection terminal that is electrically coupled to one end of the signal lines and supplies an inspection signal to the signal lines;
a detection circuit that is electrically coupled to another end of the signal lines and detects a defect in the signal lines;
a second inspection terminal that supplies a control signal that controls a detection operation of the detection circuit; and
a protection element that is electrically coupled to the second inspection terminal and absorbs a surge.
